(19) United States
(12) Patent Application Publication
(10) Pub. No.: US 2006/0203869 A1
(43) Pub. Date: Sep. 14, 2006

(54) Semiconductor laser device

(75) Inventor: Masahiro Ikehara, Higashihiroshima-shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 11/352,044

(22) Filed: Feb. 9, 2006

(30) Foreign Application Priority Data
Mar. 10, 2005 (JP) 2005-067494

(51) Int. Cl. H01S 5/00

(52) U.S. Cl. 372/43.01

(57) ABSTRACT

A semiconductor laser device includes a submount and a laser chip mounted on the submount. The submount has a front-end face inclined with respect to a light-emitting face of the laser chip and a rear-end face having a shape complementary to the shape of the front-end face.

### CROSS-REFERENCE TO RELATED APPLICATION

This application is related to Japanese Patent Application No. 2005-067494 filed on Mar. 10, 2005, whose priory is claimed and the disclosure of which is incorporated by reference in its entirety.

### BACKGROUND OF THE INVENTION

1. Field of the Invention

The present invention relates to a semiconductor laser device for use in, for example, optical pickups or the like in optical disk systems.

2. Description of Related Art

An example of conventional semiconductor laser devices is shown in a plan view and a cross-sectional view of FIG. 7A and FIG. 7B (see, for example, Japanese Unexamined Patent Publication No. SHO 63(1988)-175490). This semiconductor laser device has a laser chip 3 die-bonded onto a submount 1 via a brazing material layer 2. The submount 1 has a front-end face 1a inclined in the width direction with respect to a light-emitting face 3a of the laser chip 3. This allows light incident on the front-end face 1a of the submount 1 as shown by an arrow A to be reflected in a direction different from a light-emitting direction of the laser chip 3 as shown by an arrow B (the light-emitting direction of the laser chip is opposite to the direction indicated by the arrow A). Thus, the semiconductor laser device is designed so that when a part of light emitted from the laser chip 3 and collected on an optical disk by an optical system is reflected by the optical disk and returns to the semiconductor laser device through the optical system, the returned light is not reflected in the light-emitting direction of the laser chip 3 by the front-end face 1a of the submount 1. This allows the returned light to reach the optical disk again via the optical system and be detected by a photoreceptor, whereby a reduction in the S/N (signal to noise) ratio of signals read by the optical pickup is prevented.

FIG. 8A and FIG. 8B are a plan view and a cross-sectional view of another conventional semiconductor laser device, respectively (see, for example, Japanese Unexamined Patent Publication No. 2003-86882). This semiconductor laser device has a laser chip 3 die-bonded onto a submount 1 via a brazing material layer 2. The submount 1 has a front-end face 1a inclined in the thickness direction with respect to a light-emitting face 3a of the laser chip 3. In this semiconductor laser device as well, light reflection in the light-emitting direction of the laser chip 3 is prevented by the above-mentioned effect.

The submount 1 used in the above-mentioned semiconductor laser devices is formed by dicing a wafer into rectangular solids and then inclining the front-end face 1a by an additional processing. This additional processing increases the number of steps for manufacturing, resulting in an increase in manufacturing cost of the semiconductor laser devices.

### SUMMARY OF THE INVENTION

The present invention has been made in view of the above circumstances, and it provides a semiconductor laser device which can be easily manufactured at low cost and is capable of reflecting returned light in a direction different from a light-emitting direction of a laser chip.

According to the present invention, the semiconductor laser device comprises: a submount; and a laser chip mounted on the submount, wherein the submount has a front-end face inclined with respect to a light-emitting face of the laser chip and a rear-end face having a shape complementary to the shape of the front-end face.

### BRIEF DESCRIPTION OF THE DRAWINGS

The present invention will become more fully understood from the detailed description given hereinbelow and the accompanying drawings which are given by way of illustration only, and thus are not limitative of the present invention and wherein:

FIG. 1A and FIG. 1B are a plan view and a cross-sectional view of a semiconductor laser device according to a first embodiment of the invention, respectively;

FIG. 2 is a view illustrating a dicing process to form a submount used in the semiconductor laser device of FIG. 1A and FIG. 1B;

FIG. 3A and FIG. 3B are a plan view and a cross-sectional view of a semiconductor laser device according to a second embodiment of the invention, respectively;

FIG. 4 is a view illustrating a dicing process to form a submount used in the semiconductor laser device of FIG. 3A and FIG. 3B;

FIG. 5A and FIG. 5B are a plan view and a cross-sectional view of a semiconductor laser device according to a third embodiment of the invention, respectively;

FIG. 6 is a view illustrating a dicing process to form a submount used in the semiconductor laser device of FIG. 5A and FIG. 5B;

FIG. 7A and FIG. 7B are a plan view and a cross-sectional view of a conventional semiconductor laser device, respectively; and

FIG. 8A and FIG. 8B are a plan view and a cross-sectional view of another conventional semiconductor laser device, respectively.

### DESCRIPTION OF THE PREFERRED EMBODIMENTS

The present invention provides a semiconductor laser device comprising: a submount; and a laser chip mounted on the submount, wherein the submount has a front-end face inclined with respect to a light-emitting face of the laser chip and a rear-end face having a shape complementary to the shape of the front-end face. The submount of the invention is not a rectangular solid. The front-end face of the submount usually intersects at least one of side faces, a top face or a bottom face of the submount at an acute angle.

According to the present invention, since the submount front-end and rear-end faces have complementary shapes, these front-end and rear-end faces can be formed simultaneously in a dicing process. Thus, an additional processing of the submount is not required after the dicing process, and thereby an increase in the number of steps for manufacturing can be suppressed. The dicing process is usually performed in such a manner that the front-end face of the submount intersects at least one of the side faces, the top face or the bottom face of the submount at an acute angle.

The front-end and rear-end faces of the submount are preferably formed of planes parallel to each other because the plane shape can be easily formed using a dicing blade.

The front-end face of the submount is preferably inclined in a width or thickness direction because in either case, returned light can be prevented from being reflected in a laser-emitting direction.

The laser chip (at least one of a plurality of laser chips, if applicable) is preferably mounted in such a manner that the light-emitting direction is substantially parallel to at least one of straight lines where the top face of the submount intersects the side faces thereof. Where the laser chip is mounted inclined on the submount, there occur such disadvantages that the area of the submount top face (a face onto which the laser chip is mounted) increases and a brazing material used for mounting the laser chip is nonuniformly solidified.

The present invention also provides a semiconductor laser device comprising: a submount; and a plurality of laser chips including first and second laser chips mounted on the submount, wherein the submount has a front-end face inclined with respect to at least one of light-emitting faces of the first and second laser chips and a rear-end face having a shape complementary to the shape of the front-end face, the submount having a groove for electrically separating the first and second laser chips from each other. Descriptions above may be applied to this semiconductor laser device unless contrary to the spirit of the descriptions.

Where the front-end face of the submount is inclined in a width direction, one of the first and second laser chips that needs to have a greater heat release is preferably mounted on a protruding side at the front-end face of the submount. In this case, the contact area of the laser chip and the submount is increased and thereby the heat release is improved.

The groove can be formed using the dicing blade.

The present invention will hereinafter be described by way of embodiments thereof. However, it should be understood that the present invention be not limited to these embodiments, and various modifications can be made within the scope of the invention.

### First Embodiment

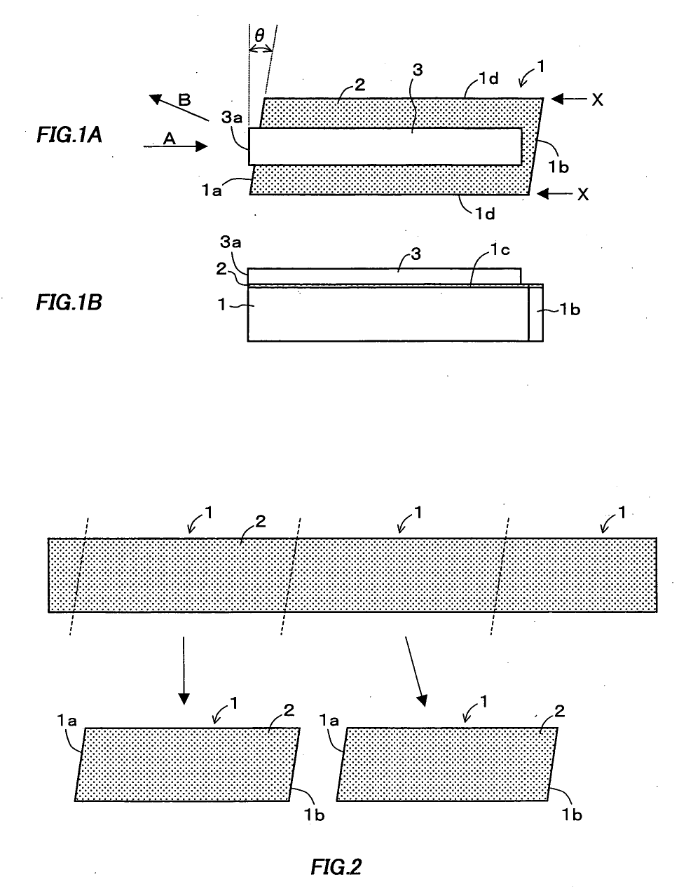

Referring to FIG. 1A and FIG. 1B, a semiconductor laser device according to a first embodiment of the invention will be described. FIG. 1A and FIG. 1B are a plan view and a cross-sectional view of the semiconductor laser device, respectively.

The semiconductor laser device includes a submount 1 and a laser chip 3 mounted on the submount 1 via a brazing material layer 2. The submount has a front-end face 1a inclined in the width direction with respect to a light-emitting face 3a of the laser chip 3 and a rear-end face 1b having a shape complementary to the shape of the front-end face 1a. A direction of light emitted from the laser chip 3 is substantially parallel to straight lines (indicated by arrows X in FIG. 1A) where a top face 1c of the submount intersects side faces Id thereof. The front-end face 1a of the submount intersects one of the side faces id thereof at an acute angle.

FIG. 2 is a plan view illustrating a dicing process to form the submount. By performing the dicing process with a dicing blade tilted in the direction shown by dotted lines in the figure, the front-end and rear-end faces 1a, 1b of the submount are formed at the same time, and the two faces have shapes complementary to each other.

An inclination angle θ of the submount front-end face 1a is preferably 4 degrees or greater. In such a case, light reflected by the front-end face 1a is displaced from an optical axis of the laser chip 3 by 8 degrees or greater. Since the laser light emitted from the laser chip 3 usually has a narrow emission angle characteristic in the width direction, an inclination angle of 4 degrees or greater is sufficient.

Further, the inclination angle θ is preferably 8 degrees or smaller. The larger the inclination angle is, the larger a difference in overhang amounts between the left and right sides of a laser chip is. Therefore, for a laser chip that needs to have the light-emitting face 3a overhanging the front-end face 1a of the submount (for example, a laser chip having a light-emitting point extremely close to a junction of the laser chip and the submount), if the inclination angle is too large, a difference in overhang amounts between the left and right sides of a laser chip is also too large, resulting in an insufficient heat release near the light-emitting face in one of the two side of the laser chip. Therefore, an excessive inclination is not preferred and the inclination angle is preferably 8 degrees or smaller.

Thus, in the first embodiment, the inclination angle θ of the submount front-end face 1a is preferably 4 to 8 degrees.

### Second Embodiment

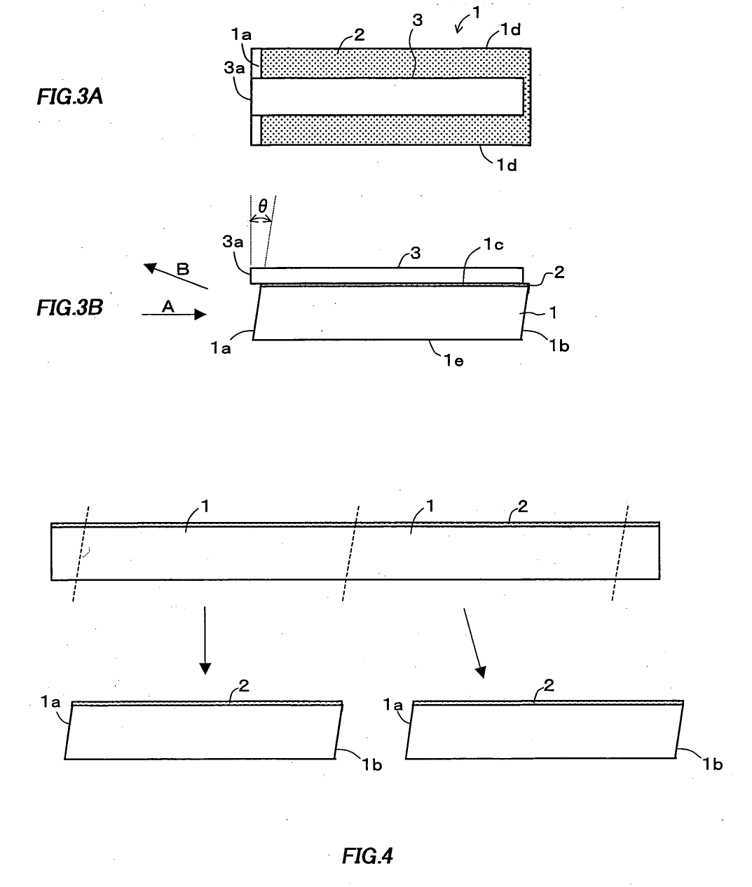

Referring to FIG. 3A and FIG. 3B, a semiconductor laser device according to a second embodiment of the invention will be described. FIG. 3A and FIG. 3B are a plan view and a cross-sectional view of the semiconductor laser device, respectively.

The semiconductor laser device includes a submount 1 and a laser chip 3 mounted on the submount 1 via a brazing material layer 2. The submount has a front-end face 1a inclined in the thickness direction with respect to a light-emitting face 3a of the laser chip 3 and a rear-end face 1b having a shape complementary to the shape of the front-end face 1a. A direction of light emitted from the laser chip 3 is substantially parallel to straight lines where a top face 1c of the submount intersects side faces 1d thereof. The front-end face 1a of the submount intersects a bottom face 1e thereof at an acute angle.

FIG. 4 is a cross-sectional view illustrating a dicing process to form the submount. By performing the dicing process with a dicing blade tilted in the direction shown by dotted lines in the figure, the front-end and rear-end faces 1a, 1b of the submount are formed at the same time and the two faces have shapes complementary to each other.

An inclination angle θ of the submount front-end face 1a is preferably 8 degrees or greater. In such a case, light reflected by the front-end face 1a is displaced from an optical axis of the laser chip 3 by 16 degrees or greater. Since the laser light emitted from the laser chip 3 usually has a wide emission angle characteristic in the thickness direction, the inclination angle is preferably 8 degrees or greater.

Further, the inclination angle θ is preferably 16 degrees or smaller. Where the inclination angle is too wide, the dicing process can be difficult.

The front-end face 1a of the submount may be inclined in both the width and thickness directions. In such a case, light reflected from the front-end face 1a is directed in a slanting direction. The front-end face 1a of the submount may be a curved face.

### Third Embodiment

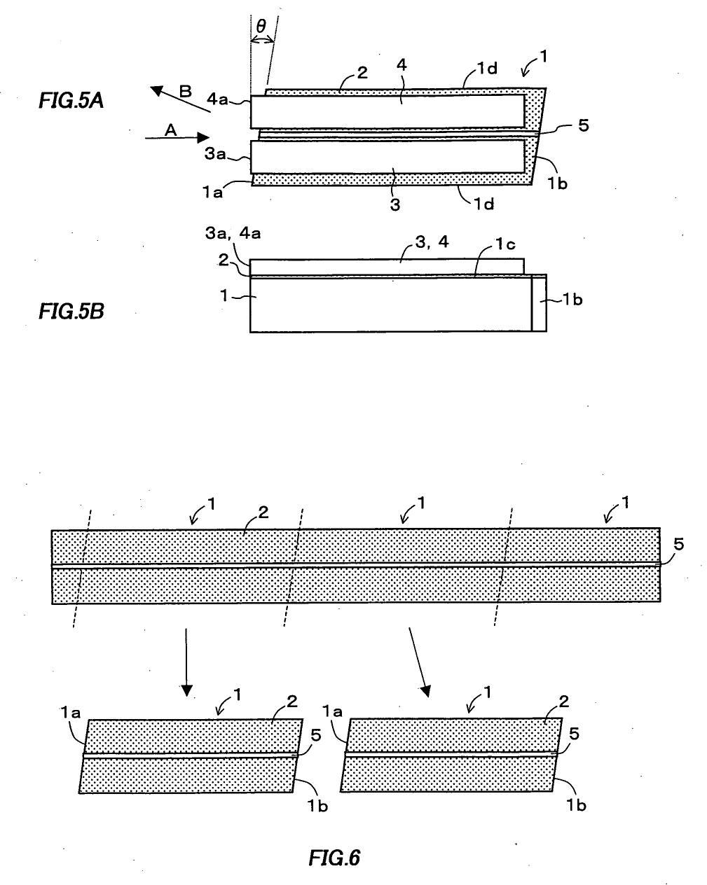

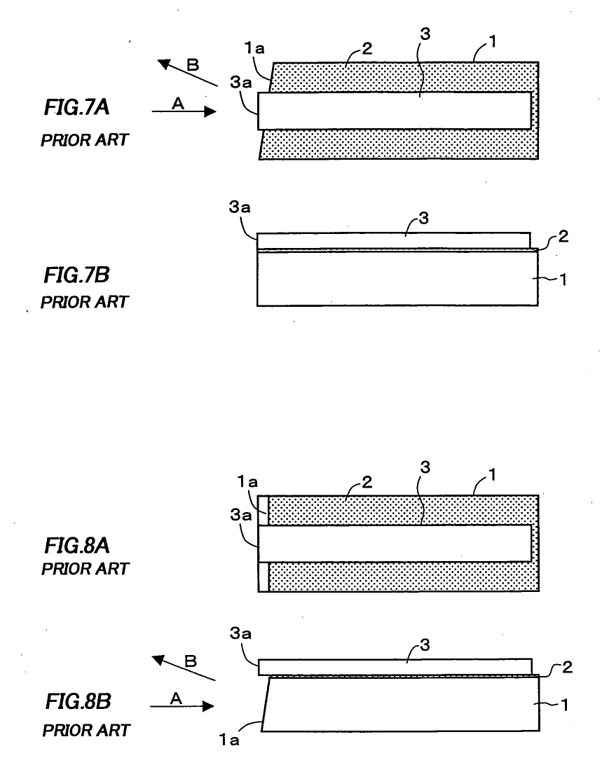

Referring to FIG. 5A and FIG. 5B, a semiconductor laser device according to a third embodiment of the invention will be described. FIG. 5A and FIG. 5B are a plan view and a cross-sectional view of the semiconductor laser device, respectively.

The semiconductor laser device includes a submount 1 and first and second laser chips 3, 4 mounted on the submount 1 via a brazing material layer 2. The submount 1 has a front-end face 1a inclined in the width direction with respect to light-emitting faces 3a, 4a of the first and second laser chips 3, 4 and a rear-end face 1b having a shape complementary to the shape of the front-end face 1a. A direction of light emitted from the laser chips 3, 4 is substantially parallel to straight lines where a top face 1c of the submount intersects side faces id thereof. The front-end face 1a of the submount intersects one of the side faces 1d thereof at an acute angle. Further, the submount 1 has a groove 5 formed therein for electrically separating the first and second laser chips 3, 4 from each other. The groove 5 divides the brazing material layer 2 and reaches the submount 1.

FIG. 6 is a cross-sectional view illustrating a dicing process to form the submount. First, the groove 5 is formed using a dicing blade, and then, the dicing process is performed with the dicing blade tilted in a direction shown by dotted lines in the figure. This allows the groove 5 to be easily formed in a process where a dicing blade is used.

The groove 5 preferably has a width of 10 μm to 50 μm. Where the width is greater than 10 μm, the first and second laser chips 3, 4 can be surely electrically divided. Where the width is smaller than 50 μm, the distance between light-emitting points of the first and second laser chips 3, 4 is not too wide. The groove preferably has a depth of 10 μm to 100 μm. Where the depth is greater than 10 μm, the first and second laser chips 3, 4 can be surely electrically divided. Where the depth is smaller than 100 μm, detrimental effects, for example, a long processing time, severe wearing of the blade, easy cracking of the submount 1, are not crucial.

Of the first and second laser chips 3,4, one that needs to have a greater heat release is preferably disposed on the protruding side at the front-end face of the submount (in FIG. 5, the first laser chip 3 side). With this arrangement, the laser chip that needs to have a greater heat release can have a greater contact area with the submount 1, and thereby the heat release is improved.

The invention thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor laser device comprising:
a submount; and
a laser chip mounted on the submount,
wherein the submount has a front-end face inclined with respect to a light-emitting face of the laser chip and a rear-end face having a shape complementary to the shape of the front-end face.

2. A semiconductor laser device comprising:
a submount; and
a plurality of laser chips including first and second laser chips mounted on the submount,
wherein the submount has a front-end face inclined with respect to at least one of light-emitting faces of the first and second laser chips and a rear-end face having a shape complementary to the shape of the front-end face, the submount having a groove for electrically separating the first and second laser chips from each other.

3. The semiconductor laser device of claim 1, wherein the front-end and rear-end faces of the submount are formed of planes parallel to each other.

4. The semiconductor laser device of claim 2, wherein the front-end and rear-end faces of the submount are formed of planes parallel to each other.

5. The semiconductor laser device of claim 1, wherein the front-end face of the submount is inclined in a width direction at an angle of 4 to 8 degrees.

6. The semiconductor laser device of claim 2, wherein the front-end face of the submount is inclined in a width direction at an angle of 4 to 8 degrees.

7. The semiconductor laser device of claim 1, wherein the front-end face of the submount is inclined in a thickness direction at an angle of 8 to 20 degrees.

8. The semiconductor laser device of claim 2, wherein the front-end face of the submount is inclined in a thickness direction at an angle of 8 to 20 degrees.

9. The semiconductor laser device of claim 1, wherein the front-end face of the submount intersects at least one of side faces, a top face, or a bottom face of the submount at an acute angle,

10. The semiconductor laser device of claim 2, wherein the front-end face of the submount intersects at least one of side faces, a top face, or a bottom face of the submount at an acute angle,

11. The semiconductor laser device of claim 1, wherein the laser chip is mounted on the submount in such a manner that a light-emitting direction of the laser chip is substantially parallel to at least one of straight lines where a top face of the submount intersects side faces thereof.

12. The semiconductor laser device of claim 2, wherein at least one of the first and second laser chips is mounted on the submount in such a manner that a light-emitting direction of the laser chip is substantially parallel to at least one of straight lines where a top face of the submount intersects side faces thereof.

13. The semiconductor laser device of claim 2, wherein the groove has a width of 10 μm to 50 μm and a depth of 10 μm to 100 μm.

14. The semiconductor laser device of claim 2, wherein the front-end face of the submount is inclined in a width direction, and one of the first and second laser chips that needs to have a greater heat release is mounted on a protruding side at the front-end face of the submount.

15. A method for manufacturing the semiconductor laser device, the semiconductor laser device comprising: a submount; and a laser chip mounted on the submount, wherein the submount has a front-end face inclined with respect to a light-emitting face of the laser chip and a rear-end face having a shape complementary to the shape of the front-end face, the method comprising the step of performing a dicing process to form the submount, wherein the front-end and rear-end faces of the submount are simultaneously formed in the dicing process.

16. A method for manufacturing the semiconductor laser device, the semiconductor laser device comprising: a submount; and a plurality of laser chips including first and second laser chips mounted on the submount, wherein the submount has a front-end face inclined with respect to at least one of light-emitting faces of the first and second laser chips and a rear-end face having a shape complementary to the shape of the front-end face, the submount having a groove for electrically separating the first and second laser chips from each other, the method comprising the step of performing a dicing process to form the submount, wherein the front-end and rear-end faces of the submount are simultaneously formed in the dicing process.

17. The method of claim 15, wherein the dicing process is performed in such a manner that the front-end face of the submount intersects at least one of side faces, a top face or a bottom face of the submount at an acute angle.

18. The method of claim 16, wherein the dicing process is performed in such a manner that the front-end face of the submount intersects at least one of side faces, a top face or a bottom face of the submount at an acute angle.

19. The method of claim 15, wherein the laser chip is mounted in such a manner that a light-emitting direction thereof is substantially parallel to at least one of straight lines where a top face of the submount intersects side faces thereof.

20. The method of claim 16, wherein at least one of the first and second laser chips is mounted in such a manner that a light-emitting direction thereof is substantially parallel to at least one of straight lines where a top face of the submount intersects side faces thereof.

21. The method of claim 16, further comprising the step of forming the groove using a dicing blade.
